(19) United States
(12) Patent Application Publication
(10) Pub. No.: US 2008/0265428 A1
(43) Pub. Date: Oct. 30, 2008

(54) VIA AND SOLDER BALL SHAPES TO MAXIMIZE CHIP OR SILICON CARRIER STRENGTH RELATIVE TO THERMAL OR BENDING LOAD ZERO POINT

(75) Inventor: Bucknell C. Webb, Ossining, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/740,325

(22) Filed: Apr. 26, 2007

(51) Int. Cl. H01L 23/488

(52) U.S. Cl. 257/774; 257/E23.011

(57) ABSTRACT

A method of modifying via and solder ball shapes for maximizing semiconductor chip or silicon carrier strengths relative to thermal expansion and bending load zero points. The method entails modifying circular annular vias into elliptical annular vias so as to reduce stress concentration factors in the chip or carrier at the vias and solder balls. The reduction in the stress concentration is effected in the semiconductor chip or silicon carrier in regions proximate the vias and in wiring layers at the ends of the vias.

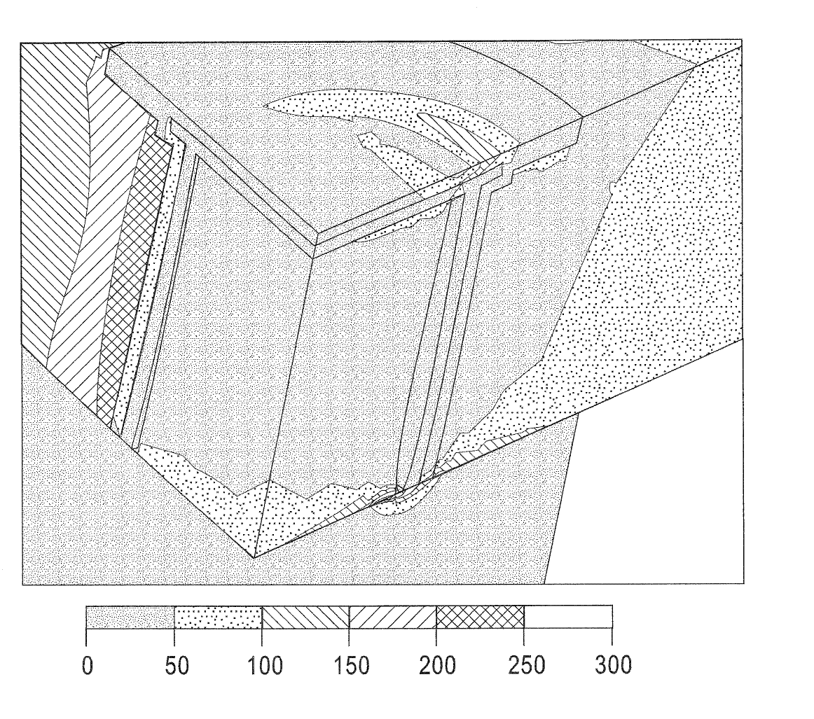

### BACKGROUND OF THE INVENTION

### Field of the Invention

The present invention relates to a method of modifying via and solder ball shapes in order to be able to maximize semiconductor chip or silicon carrier strength relative to thermal or bending load zero points.

The foregoing has, to some extent, been addressed in the semiconductor technology, wherein diverse electrical through-via designs for silicon carriers and chips have been proposed. In various of those designs, for example, copper annular partially filled, paste filled, and solder filled AML designs, the fill material in the aperture, which has been created for the via, may not completely fill the via, may be subject to a weak seam or adhesion point, or may be of substantially lower modulus than the fill material. In that instance, the stress, which is due to bending or stretching of the chip or the mounting stresses or those generated by thermal expansion during use, can readily lead to stress concentrations in the silicon material around the via and in the wiring layers at the ends of the via. These loads or stresses are concentrated in the direction of the bending or expansion of the material, which can be predicted by a method of finite element modeling, and is usually defined by a simple function of the distance from the mounting thermal expansion neutral point.

Accordingly, the invention resides in altering the cross-sectional shape of the via, based on the knowledge of the load direction and amplitudes to minimize the risk of chip damage. In order to implement the foregoing, pursuant to the invention, the latter is directed to the following aspects:

The inventive concept is essentially directed to the use of elliptical annular vias instead of circular annular vias. Hereby, the long axis of the ellipse would be aligned along the radius from the thermal expansion neutral point. In order to avoid changing the via density, the long axis dimension should preferably not be changed; rather the short axis of the ellipse would be reduced or shortened. With annular vias, the circumference of the via, and thus the resistance thereof would only change as the square root of the short dimension, consequently, for a factor of two, a change of the resistance would only increase by 1.4. Since the via resistance is generally small, this would matter. For the same case, a simple two dimensional plate theory predicts that the uniaxial stress concentration proceeds as the ratio of the axes, so that the stress reduction in the neutral point direction would be a factor of 2; although the via would become more sensitive to loads in the other direction, but this may be unimportant in nature.

The pad shapes and attached solder balls could also be made elliptical but this would put requirements on the via ball density, so it may not be economically feasible. Changing the pad shapes would primarily be useful if no underfill is contemplated, as may be the case for the micro-C4s for chip attachment.

### BRIEF DESCRIPTION OF THE DRAWING

Reference may now be made to the following detailed description of the invention, taken in conjunction with the accompanying single FIGURE of drawing representing a model for a circular annular partially filled via.

### DETAILED DESCRIPTION OF THE INVENTION

As illustrated in the drawing, pursuant to the invention, the following is deemed to be of particular significance:

The expected loads, as represented through modeling, would determine the degree of ellipiticity. It is noted that the stress concentration is not a function of the overall via size, but only its shape. The invention would be primarily useful for vias with a weak layer, such as partially filled or seamed vias, whereby modeling indicates that fully filled vias are nearly as strong as solid silicon material.

Represented is a model in the illustrated drawing for a circular annular, partially filled via under 100 MPa uniaxial tensional stress showing principal stress concentrations around the via and in wiring layers:

The stress along the side of the via is amplified by a factor of over 2.75 and in the wiring layers by about 1.25. The formula for uniaxial stress concentration for an elliptical hole in an infinite plate is (1+2a/b) where a and b are the principal radii of the ellipse. Expected is a stress concentration of 3 in this case. The finite element result is slightly lower because part of the stress is transmitted to the solder ball and wiring layers. For a 2:1 elliptical shape, the infinite plate uniaxial stress concentration factor is reduced to 2, a reduction to ⅔ from the circular case.

In summation, the foregoing clearly demonstrates the advantages obtained by utilizing an elliptical shape in comparison with the circular configuration, which results in the uniaxial stresses having their concentration factors reduced by a considerable amount.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but to fall within the spirit and scope of the appended claims.

What is claimed is:

1. A method of modifying via and solder ball shapes for maximizing semiconductor chip or silicon carrier strengths relative to thermal expansion and bending load zero points, said method comprising modifying circular annular vias into elliptical annular vias so as to reduce stress concentration factors in said chip or carrier at said vias and solder balls.

2. A method as claimed in claim 1, wherein said reduction in the stress concentration is effected in said semiconductor chip or silicon carrier in regions proximate said vias and in wiring layers at the ends of said vias.

3. A method as claimed in claim 1, wherein said elliptical annular vias each have the long axis of the ellipse thereof aligned along a radius extending from a thermal expansion neutral point.

4. A method as claimed in claim 3, wherein the short axis of the ellipse of each of said elliptical annular vias is reduced so as to avoid changing the via density along the long axis of said elliptical annular vias.
